(19) United States
(12) Patent Application Publication
(10) Pub. No.: US 2023/0238480 A1
(43) Pub. Date: Jul. 27, 2023

(54) RADIATION EMITTING SEMICONDUCTOR CHIP

(71) Applicant: ams-OSRAM International GmbH, Regensburg (DE)

(72) Inventor: Ivar TANGRING, Regensburg (DE)

(21) Appl. No.: 17/999,946

(22) PCT Filed: May 28, 2021
(86) PCT No.: PCT/EP2021/064413

§ 371 Date: Nov. 28, 2022

(30) Foreign Application Priority Data
Jun. 3, 2020 (DE) 10 2020 114 772.4

(51) Int. Cl. H01L 33/14; H01L 33/62

(52) U.S. Cl. CPC H01L 33/14; H01L 33/62

(57) ABSTRACT

A radiation emitting semiconductor chip may include a first semiconductor layer sequence, a second semiconductor layer sequence arranged on the first semiconductor layer sequence, a first contact structure configured to inject charge carriers into the first semiconductor layer sequence, and a contact layer sequence configured to inject charge carriers into the second semiconductor layer sequence. The first contact structure and the contact layer sequence may be formed without overlapping in lateral directions in plan view. The contact layer sequence may have a sheet resistance, which increases in the direction of the first contact structure.

### CROSS-REFERENCE TO RELATED APPLICATIONS

The present application is a national stage entry according to 35 U.S.C. § 371 of PCT application No.: PCT/EP2021/064413 filed on May 28, 2021; which claims priority to German patent application DE 10 2020 114 772.4, filed on Jun. 3, 2020; all of which are incorporated herein by reference in their entirety and for all purposes.

### TECHNICAL FIELD

A radiation emitting semiconductor chip is specified.

### BACKGROUND

An objective to be solved is to specify a radiation emitting semiconductor chip, which has a particularly homogeneous brightness.

### SUMMARY

For example, the radiation emitting semiconductor chip is configured to emit electromagnetic radiation from a radiation exit surface during operation. The electromagnetic radiation emitted from the radiation emitting semiconductor chip can be near-ultraviolet radiation, visible light, and/or near-infrared radiation.

For example, the radiation emitting semiconductor chip has a main extension plane. A vertical direction extends perpendicular to the main extension plane and lateral directions extend parallel to the main extension plane.

According to at least one embodiment, the radiation emitting semiconductor chip comprises a first semiconductor layer sequence. In addition, the radiation emitting semiconductor chip comprises a second semiconductor layer sequence arranged on the first semiconductor layer sequence. For example, the first semiconductor layer sequence and the second semiconductor layer sequence are epitaxially grown on top of one another in a vertical direction.

For example, the first semiconductor layer sequence is n-doped and thus formed n-conductive. Furthermore, the second semiconductor layer sequence is, for example, p-doped and thus formed p-conductive.

For example, an active region is arranged between the first semiconductor layer sequence and the second semiconductor layer sequence. The active region is configured to generate electromagnetic radiation emitted from the radiation exit surface during operation. For example, the active region is directly adjacent to the first semiconductor layer sequence and the second semiconductor layer sequence. The active region has, for example, a pn junction for generating the electromagnetic radiation, such as a double heterostructure, a single quantum well structure, or a multiple quantum well structure.

For example, the first semiconductor layer sequence and the second semiconductor layer sequence are based on a III-V compound semiconductor material. The compound semiconductor material can be, for example, a nitride compound semiconductor material, a phosphide compound semiconductor material, or an arsenide compound semiconductor material.

Nitride compound semiconductor materials are compound semiconductor materials containing nitride, such as the materials from the system InₓAl_{y}Ga_{1-x-y}N with 0≤x≤1, 0≤y≤1 and x+y≤1.

Phosphide compound semiconductor materials are compound semiconductor materials containing phosphide, such as the materials from the system InₓAl_{y}Ga_{1-x-y}P with 0≤x≤1, 0≤y≤1 and x+y≤1.

Furthermore, arsenide compound semiconductor materials are compound semiconductor materials containing arsenic, such as the materials from the system InₓAl_{y}Ga_{1-x-y}As with 0≤x≤1, 0≤y≤1 and x+y≤1.

According to at least one embodiment, the radiation emitting semiconductor chip comprises a first contact structure configured to inject charge carriers into the first semiconductor layer. That is, the first contact structure is configured to inject a current into the first semiconductor layer sequence. In this embodiment, the first semiconductor layer sequence is in particular an n-doped semiconductor layer sequence.

For example, the first contact structure extends along a main extension direction in lateral directions. Alternatively, the first contact structure can extend in the lateral directions along a closed shape, such as a ring or polygon. Further, in plan view, the first contact structure can extend in the lateral directions along a simple connected surface having a shape of a circle and/or a polygon.

The plan view in the lateral directions is oriented along the vertical direction here and in the following.

For example, the first contact structure has or consists of an electrically conductive metal. The metal is for example one of the following materials: copper, gold, platinum, titanium, aluminum, silver.

According to at least one embodiment, the radiation emitting semiconductor chip comprises a contact layer sequence configured to inject charge carriers into the second semiconductor layer sequence. For example, the contact layer sequence is in direct contact with the second semiconductor layer sequence in places. That is, the first contact structure is configured to inject a current into the first semiconductor layer sequence. For example, the contact layer sequence covers at least 90% of the second semiconductor layer sequence. In particular, the contact layer sequence covers at least 95% or at least 99% of the second semiconductor layer sequence.

In this embodiment, the second semiconductor layer sequence is in particular a p-doped semiconductor layer sequence.

According to at least one embodiment of the radiation emitting semiconductor chip, the first contact structure and the contact layer sequence are formed without overlapping in lateral directions in plan view. In this case, the first contact structure and the contact layer sequence in particular do not overlap in lateral directions in plan view.

Furthermore, the first contact structure and the contact layer sequence are arranged spaced apart from one another in lateral directions, for example.

According to at least one embodiment of the radiation emitting semiconductor chip, the contact layer sequence has a sheet resistance, which increases in direction of the first contact structure. The sheet resistance of the contact layer sequence has, for example, a gradient in direction of the first contact structure. The gradient can be a continuous gradient, for example. In this case, the sheet resistance of the contact layer sequence increases continuously in direction of the first contact structure.

Alternatively, it is possible that the gradient is a discrete gradient. In this case, the gradient corresponds to a step function, for example. In this case, the sheet resistance of the contact layer sequence increases in discrete steps in direction of the first contact structure.

For example, the second semiconductor layer sequence, which is in particular p-doped, exhibits a poorer conductivity in lateral directions than the first semiconductor layer sequence, which is in particular n-doped. Since the conductivity in lateral directions is usually inversely proportional to a sheet resistance, the second semiconductor layer sequence exhibits a higher sheet resistance than the first semiconductor layer sequence.

Further, for example, a series resistance experienced by a charge carrier to be impressed into the first semiconductor layer sequence and/or a charge carrier to be impressed into the second semiconductor layer sequence is proportional to a path length of the charge carrier in the corresponding semiconductor layer sequence. For example, a series resistance along a path starting from the first contact structure to a virtual point on the first contact layer sequence is different from a series resistance along another path starting from the first contact structure to another virtual point on the contact layer sequence. Thus, a charge carrier density and, in particular, a current density can be formed inhomogeneously in the active region.

An idea is that the sheet resistance of the contact layer sequence increases in the direction of the first contact structure. Due to this increasing sheet resistance, the series resistances along different paths can be advantageously matched. This equalization of the series resistances along different paths advantageously results in a particularly homogeneous current density in the active region. This also advantageously improves the quantum efficiency of the radiation emitting semiconductor chip.

According to at least one embodiment of the radiation emitting semiconductor chip, a second contact structure is arranged on the contact layer sequence. The second contact structure and the contact layer sequence are, for example, in regions in direct contact. The second contact structure is configured, for example, to impress charge carriers into the second semiconductor layer sequence. In other words, the second contact structure is configured to impress current into the second semiconductor layer sequence via the contact layer sequence.

The second contact structure covers the contact layer sequence to a large extent, for example. In this context, “to a large extent” means in particular that the second contact structure covers at least 90% of the contact layer sequence. In particular, the second contact structure covers at least 95% or at least 99% of the contact layer sequence. Alternatively, second contact structure extends in lateral directions, for example, along a main extension direction in lateral directions. Further, the second contact structure can extend in plan view in lateral directions along a simple connected surface having a shape of a circle and/or a polygon.

The second contact structure may have or consist of an electrically conductive metal. The metal is one of the following materials: copper, gold, platinum, titanium, aluminum, silver.

According to at least one embodiment of the radiation emitting semiconductor chip, an electrically insulating layer is arranged in regions between the second contact structure and the contact layer sequence. For example, the second contact structure is in regions in direct contact with the contact layer sequence. The electrically insulating layer covers at least 90% of the contact layer sequence. In particular, the electrically insulating layer covers at least 95% or at least 99% of the contact layer sequence.

For example, the electrically insulating layer comprises an electrically insulating material, such as a dielectric material.

According to at least one embodiment of the radiation emitting semiconductor chip, the electrically insulating layer has at least one first recess in which the second contact structure and the contact layer sequence are in electrically conductive contact. The first recess penetrates the electrically insulating layer completely, for example. For example, charge carriers can be impressed exclusively through the first recess from the second contact structure via the contact layer sequence into the second semiconductor layer sequence.

The first recess extends, for example, along a main extension direction in lateral directions. For example, the first recess has a width of at least 100 nm and at most 25 μm. In particular, the first recess has a width of at least 1 μm and at most 10 μm or at least 1 μm and at most 5 μm. For example, the first recess has a width of approximately 5 μm. The width of the first recess corresponds to a minimum extension of the first recess in lateral directions.

According to at least one embodiment of the radiation emitting semiconductor chip, the second contact structure comprises a first sublayer and a second sublayer. The first sublayer and the second sublayer are arranged, for example, stacked on top of one another in the vertical direction. The first sublayer and the second sublayer are in direct contact with one another, for example.

According to at least one embodiment of the radiation emitting semiconductor chip, the first sublayer is a reflective layer. The reflective layer is arranged, for example, between the second semiconductor layer sequence and the second sublayer.

The reflective layer comprises, for example, a reflective metal such as silver. In this case, the reflective layer is formed electrically conductive. The reflective layer has, for example, a reflectivity of at least 90%, in particular at least 95%, for the electromagnetic radiation generated by the active region.

According to at least one embodiment of the radiation emitting semiconductor chip, the second sublayer is a metallic layer. The metallic layer is arranged, for example, on a side of the reflective layer facing away from the second semiconductor layer sequence.

For example, the metallic layer comprises one or more of the following materials: copper, gold, platinum, titanium, aluminum, silver.

According to at least one embodiment of the radiation emitting semiconductor chip, the contact layer sequence comprises a first current spreading layer which is in direct contact with the second semiconductor layer sequence. In particular, the first current spreading layer is arranged between the second semiconductor layer sequence and the second contact structure.

For example, the first current spreading layer is to a large extent in direct contact with the second semiconductor layer sequence. In this case, “to a large extent” means that the first current spreading layer covers at least 90% of the second semiconductor layer sequence. In particular, the first current spreading layer covers at least 95% or at least 99% of the second semiconductor layer sequence. Alternatively, it is possible that the first current spreading layer completely covers the second semiconductor layer sequence.

According to at least one embodiment of the radiation emitting semiconductor chip, the contact layer sequence comprises a second current spreading layer which is in regions in direct contact with the second contact structure. For example, the second current spreading layer is arranged between the first current spreading layer and the second contact structure.

The first current spreading layer and/or the second current spreading layer are, for example, formed to be transparent to the electromagnetic radiation generated by the active region. The first current spreading layer and/or the second current spreading layer are formed, for example, with a transparent, electrically conductive material. The electrically conductive material is, for example, an electrically conductive metal or a transparent electrically conductive oxide (TCO). For example, zinc oxide, tin oxide, cadmium oxide, titanium oxide, indium oxide or indium tin oxide (ITO) are TCOs. For example, TCOs are provided with a dopant. The dopant can be configured to increase the electrical conductivity of the TCOs.

The first current spreading layer and/or the second current spreading layer may be configured to absorb at most 4%, in particular at most 2%, of the electromagnetic radiation generated by the active region. That is, the first current spreading layer and/or the second current spreading layer transmit at least 96%, in particular at least 98%, of the electromagnetic radiation generated by the active region.

According to at least one embodiment of the radiation emitting semiconductor chip, a height in vertical direction of the first current spreading layer is smaller than a height in vertical direction of the second current spreading layer. In this case, a height in vertical direction corresponds to a largest expansion of the first current spreading layer and/or the second current spreading layer in vertical direction.

If the electromagnetic radiation generated by the active region is absorbed, it is, for example, a free charge carrier absorption. This absorption is usually proportional to the height of the first current spreading layer and/or the height of the second current spreading layer.

The height of the first current spreading layer is, for example, at least 5 nm and at most 50 nm, in particular at least 15 nm and at most 30 nm. The height of the second current spreading layer is, for example, at least 50 nm and at most 1 μm, in particular at least 100 nm and at most 400 nm.

According to at least one embodiment of the radiation emitting semiconductor chip, a cross-sectional area in vertical direction of the second current spreading layer decreases in the direction of the first contact structure. In this embodiment, the radiation emitting semiconductor chip can have only a first current spreading layer. In this case, the second current spreading layer is in direct contact with the second semiconductor layer sequence, for example, to a large extent. In this case, the second current spreading layer covers at least 90% of the second semiconductor layer sequence. In particular, the second current spreading layer covers at least 95% or at least 99% of the second semiconductor layer sequence. Alternatively, the first current spreading layer is arranged between the second current spreading layer and the second semiconductor layer sequence.

The cross-sectional area in vertical direction of the second current spreading layer towards the contact structure has, for example, a step shape. For example, the step shape has two or more steps. For example, an outer surface facing away from the second semiconductor layer sequence has the step shape. In this case, the sheet resistance of the contact layer sequence increases in discrete steps in the direction of the first contact structure.

For example, the height of the second current spreading layer in a region that is arranged closest to the first contact structure is formed to be smaller than the height of the first current spreading layer in a region that is arranged closest to the first recess, for example, by a factor of 2 to 10, in particular by a factor of 6.

The sheet resistance of the contact layer sequence is usually inversely proportional to the height of the contact layer sequence. In this case, a cross-sectional area in vertical direction of the first current spreading layer that is arranged closest to the first contact structure has a sheet resistance that is lower by a factor of 2 to 10, in particular by a factor of 6, than a cross-sectional area in the vertical direction of the first current spreading layer that is arranged closest to the first recess. This increases the sheet resistance of the contact layer sequence in direction of the first contact structure.

Alternatively or additionally, it is possible that the second semiconductor layer sequence is doped to different degrees in the regions of different steps.

According to at least one embodiment of the radiation emitting semiconductor chip, a cross-sectional area in lateral directions of the second current spreading layer decreases towards the first contact structure. For example, if the radiation emitting semiconductor chip comprises the first current spreading layer and the second current spreading layer, the first current spreading layer is in direct contact with the second semiconductor layer sequence.

Alternatively, the radiation emitting semiconductor chip is free of the first current spreading layer. In this case, the second current spreading layer is in direct contact with the second semiconductor layer sequence.

The second current spreading layer has at least one opening, for example. This opening extends, for example, in vertical direction completely through the second current spreading layer and the dielectric layer. An area portion of the opening increases, for example, in direction of the first contact structure. Thus, the cross-sectional area in lateral directions of the second current spreading layer decreases towards the first contact structure. For example, the opening is shaped such that the cross-sectional area in lateral directions of the second current spreading layer tapers towards the first contact structure.

Alternatively, the second current spreading layer has a plurality of openings. In this case, a density of the openings increases in the direction of the first contact structure. Alternatively or additionally, cross-sectional areas in lateral directions of the openings can decrease starting from the first contact structure towards the first recess.

With such openings in the second current spreading layer, the sheet resistance of the contact layer sequence can continuously increase in direction of the first contact structure.

The sheet resistance of the contact layer sequence is usually, inter alia, inversely proportional to the cross-sectional area in lateral directions of the second current spreading layer. That is, if a cross-sectional area in lateral directions of the second current spreading layer decreases in direction of the first contact structure, the sheet resistance of the contact layer sequence increases in direction of the first contact structure.

According to at least one embodiment of the radiation emitting semiconductor chip, the contact layer sequence comprises a dielectric layer arranged in regions between the first current spreading layer and the second current spreading layer. For example, the first current spreading layer and the second current spreading layer are in direct contact with the dielectric layer. In regions where the dielectric layer is arranged between the first current spreading layer and the second current spreading layer, the first current spreading layer and the second current spreading layer are not in direct contact with one another.

The dielectric layer comprises, for example, a dielectric material or is formed from a dielectric material.

Furthermore, the dielectric layer is, for example, electrically insulating.

The dielectric layer may have a refractive index that is smaller than a refractive index of the first current spreading layer and/or a refractive index of the second current spreading layer. For example, the refractive index of the first current spreading layer and/or the refractive index of the second current spreading layer is at least 1.5 and at most 2.0, in particular at least 1.7 and at most 2.0. For example, the refractive index of the dielectric layer is at least 1.38 and at most 1.8, in particular approximately 1.46 or approximately 1.50. In particular, the refractive index of the dielectric layer is at least 0.2 smaller than the refractive index of the first current spreading layer and/or the second current spreading layer.

By using the dielectric layer, the second current spreading layer does not have to be considered in terms of absorption losses of electromagnetic radiation. For example, the dielectric layer has a thickness in vertical direction. The thickness corresponds to at least 0.3 times a wavelength of the electromagnetic radiation. If the electromagnetic radiation has a wavelength of 450 nm, the thickness of the dielectric layer is at least 135 nm.

According to at least one embodiment of the method, the dielectric layer has second recesses. The second recesses penetrate the dielectric layer completely, for example. The second recesses are arranged, for example, at grid points of a grid. The grid is in particular a polygonal grid, such as an orthogonal grid or a hexagonal grid. The grid is, for example, a regular grid. Alternatively, the grid is an irregular grid.

For example, the second recesses each have a diameter of at least 100 nm and at most 10 μm. The diameter corresponds to a maximum extension in lateral directions of one of the second recesses. For example, the diameters of each second recess are approximately 1 μm. Furthermore, the second recesses have a distance between one another in lateral directions of, for example, at least 10 μm and at most 50 μm.

For example, the second recesses have an area portion of at most 5%, in particular at most 1%, of an area in lateral directions of the dielectric layer.

According to at least one embodiment of the radiation emitting semiconductor chip, the first current spreading layer is in direct contact with the second current spreading layer in the second recesses. In this case, charge carriers from the second current spreading layer can be impressed into the second semiconductor layer sequence exclusively via the second recesses.

According to at least one embodiment of the radiation emitting semiconductor chip, the contact layer sequence comprises at least two metallic subsegments and at least one connecting layer. For example, the metallic subsegments are in direct contact with the second semiconductor layer sequence. The metallic subsegments are arranged spaced apart from one another in lateral directions, for example. That is, the metallic subsegments are not in direct contact with one another at any point. Furthermore, the metallic subsegments are arranged in a common plane in lateral directions, for example.

For example, the metallic subsegments have a distance in lateral directions of at least 500 nm and at most 5 μm. For example, the distance between directly adjacent metallic subsegments is approximately 2 μm. The distance in lateral directions corresponds in particular to a minimum distance between two directly adjacent metallic subsegments.

Areas in lateral directions of the metallic subsegments can also be formed different in size. Each of the metallic subsegments has, for example, an inhomogeneous current distribution over its area in lateral directions. For a particularly homogeneous current density in the active region, an area in lateral directions of the metallic subsegments decreases in the direction of the first contact structure. That is, an area in lateral directions of the metallic subsegments can decrease from the first recess towards the first contact structure. Alternatively, the metallic subsegments are formed of the same size.

The metallic subsegments include, for example, an electrically conductive metal, particularly a reflective metal, such as silver.

The connecting layer is also electrically conductive and comprises, for example, electrically conductive metals or transparent electrically conductive oxides, such as ITO.

For example, the connecting layer has a height in vertical direction of at least 1 nm and at most 100 nm, for example, approximately 50 nm.

According to at least one embodiment of the radiation emitting semiconductor chip, the connecting layer electrically conductively connects the metallic subsegments to one another. In particular, the connecting layer connects directly adjacent metallic subsegments in an electrically conductive manner.

The contact layer sequence can further comprise several metallic subsegments. For example, a single connecting layer is arranged in each case between directly adjacent metallic subsegments. Alternatively, it is possible that two or more connecting layers are arranged between directly adjacent metallic subsegments.

The connecting layer can further completely cover each of the metallic subsegments.

According to at least one embodiment of the radiation emitting semiconductor chip, a resistance of the connecting layer is larger than each resistance of the metallic subsegments. The sheet resistance of the contact layer sequence can be increased by the connecting layer in direction of the first contact structure.

For example, an area of the connecting layers between directly adjacent metallic subsegments decreases towards the first contact structure. That is, a connecting layer arranged closest to the first contact structure has, for example, an area in lateral directions that is smaller by a factor of 2 to 10, in particular by a factor of 6, than a connecting layer arranged closest to the first recess. Thus, this connecting layer, which is arranged closest to the first contact structure, has, for example, a sheet resistance that is larger by a factor of 2 to 10, in particular by a factor of 6, than a connecting layer arranged closest to the first recess.

According to at least one embodiment of the radiation emitting semiconductor chip, the first contact structure is completely enclosed by each metallic subsegment in lateral directions. In this case, the first contact structure extends in plan view in lateral directions over an area having a shape of a circle and/or a polygon. The metallic subsegments completely enclose this area in lateral directions, for example.

According to at least one embodiment of the radiation emitting semiconductor chip, all metallic subsegments are completely enclosed by the first contact structure in lateral directions. In this case, the first contact structure extends along a closed shape, such as a ring or a polygon, in lateral directions. Such a contact structure completely encloses the metallic subsegments in lateral directions, for example.

In this embodiment, it is possible for the second contact structure to be completely enclosed by each metallic subsegment in lateral directions. In this case, the second contact structure extends in plan view in lateral directions over an area having a shape of a circle and/or a polygon. The metallic subsegments completely enclose this area in lateral directions, for example.

According to at least one embodiment, a further dielectric layer is arranged in lateral directions between the metallic subsegments. The further dielectric layer is formed, for example, as a dielectric mirror layer. In this case, the dielectric mirror layer is arranged completely in regions between the metallic subsegments. The dielectric mirror layer is a Bragg mirror, for example.

For example, if the radiation emitting semiconductor chip does not have a further dielectric layer, the electrically insulating layer is arranged in regions in lateral directions between the metal subsegments between which the connecting layer is not arranged.

According to at least one embodiment, the connecting layer is arranged between the further dielectric layer and the electrically insulating layer. The further dielectric layer, the connecting layer and the electrically insulating layer are arranged stacked on top of one another in the specified order in the vertical direction, in the region between the metallic subsegments, for example.

According to at least one embodiment, a length of the connecting layer between the metallic subsegments predetermines a sheet resistance of the contact layer sequence. For example, the connecting layer between the further dielectric layer and the electrically insulating layer extends in regions in lateral directions and in regions in vertical directions. As a result of such an extent, the connecting layer is extended by a factor of 2 to 10, for example, compared to a connecting layer between the metallic subsegments extending only in lateral directions. In particular, such an extended connecting layer has a sheet resistance increased by a factor of 2 to 10.

According to at least one embodiment of the radiation emitting semiconductor chip, the first contact structure and the first recess extend parallel to one another. In this embodiment, the first contact structure and the first recess each have a main extension direction in lateral directions.

In this case, the main extension direction of the first contact structure and the main extension direction of the first recess extend parallel to one another.

For example, the first contact structure and the first recess each have a length. For example, the lengths each correspond to a maximum extension in lateral directions. For example, the lengths each extend along the respective main extension direction.

By such a parallel arrangement of the first contact structure and the first recess, the charge carriers to be impressed can propagate particularly homogeneously in the first semiconductor layer sequence and/or the second semiconductor layer sequence. Advantageously, a particularly high homogeneity of the current density in the active region can thus be achieved.

According to at least one embodiment of the radiation emitting semiconductor chip, the sheet resistance of the contact layer sequence is predetermined such that an average current density in the active region does not deviate by more than 10% from a predetermined average current density. Due to such a deviation, electromagnetic radiation emitted by the radiation emitting semiconductor chip is particularly homogeneously distributed.

### BRIEF DESCRIPTION OF THE DRAWINGS

In the following, the radiation emitting semiconductor chip will be explained in more detail with reference to the Figures by means of exemplary embodiments.

FIGS. 1, 2, 3, 4, 5, 6, 7, 8, 9, and 10 schematic sectional views of a radiation emitting semiconductor chip, each according to an exemplary embodiment,

FIGS. 11, 12, and 13 schematic top view of a radiation emitting semiconductor chip, each according to an exemplary embodiment,

FIG. 14 schematic sectional view of a radiation emitting semiconductor chip, each according to an exemplary embodiment,

FIGS. 15, 16, 17, 18, 19, and 20 schematic diagrams of a radiation emitting semiconductor chip in plan view, each according to an exemplary embodiment,

FIGS. 21, 22, 23, 24, and 25 schematic sectional views of a region of a radiation emitting semiconductor chip, each according to an exemplary embodiment, and

FIGS. 26 and 27 exemplary view of current densities for different ranges for different radiation emitting semiconductor chips.

Elements that are identical, similar or have the same effect are given the same reference signs in the Figures. The Figures and the proportions of the elements shown in the Figures are not to be regarded as to scale. Rather, individual elements can be shown exaggeratedly large for better representability and/or for better comprehensibility.

### DETAILED DESCRIPTION

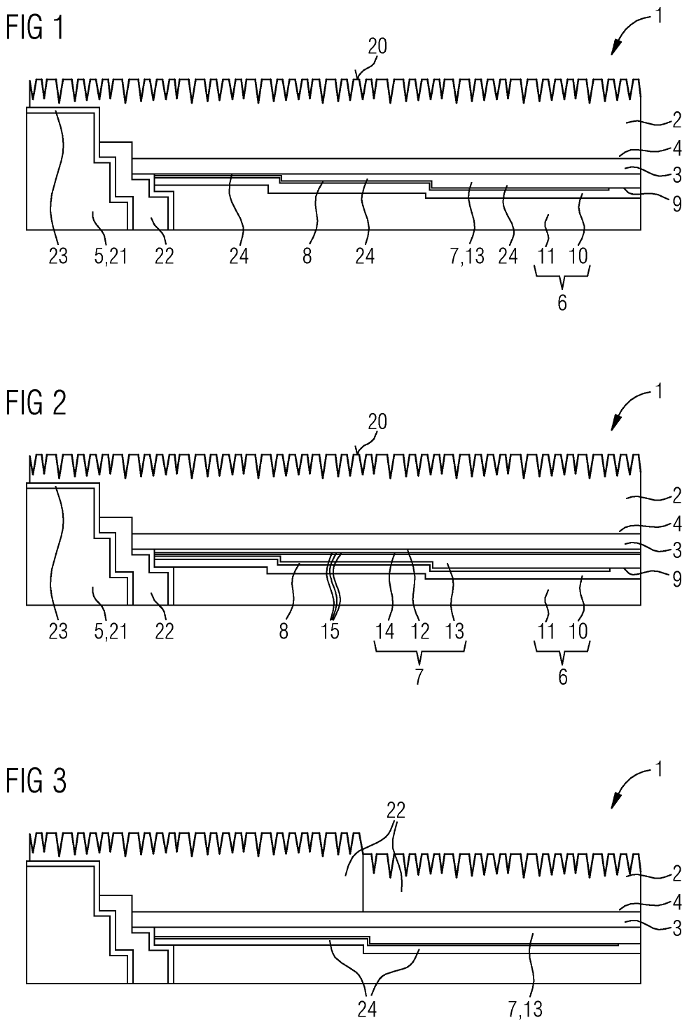

The radiation emitting semiconductor chip 1 according to the exemplary embodiment of FIG. 1 comprises a first epitaxial semiconductor layer sequence 2 of a first conductivity type and a second epitaxial semiconductor layer sequence 3 of a second conductivity type different from the first conductivity type. In this exemplary embodiment, the first semiconductor layer sequence 2 is formed n-doped. Furthermore, the second semiconductor layer sequence 3 is formed p-doped here. In this exemplary embodiment, the first semiconductor layer sequence 2 comprises a nitride compound semiconductor material such as GaN, with a height in vertical direction of approximately 1 μm.

An active region 4 is arranged between the first semiconductor layer sequence 2 and the second semiconductor layer sequence 3, which is configured to generate electromagnetic radiation emitted from a radiation exit surface 20 of the semiconductor chip 1 during operation. A top surface of the first semiconductor layer sequence 2 is patterned. Advantageously, electromagnetic radiation generated in the active region 4 can be coupled out particularly well in this way.

A contact layer sequence 7, an electrically insulating layer 8 and a second contact structure 6 are arranged on the second semiconductor layer sequence 3, in particular in the order indicated.

The second contact structure 6 comprises a first sublayer 10 and a second sublayer 11. The first sublayer 10 is a reflective layer, such as silver, which is arranged between the second semiconductor layer sequence 3 and the second sublayer 11. The second sublayer 11 is a metallic layer, which is formed to be solderable, for example.

Furthermore, an electrically insulating layer 8 is arranged in regions between the contact layer sequence 7 and the first sublayer 10. The electrically insulating layer 8 is in direct contact with the first sublayer 10 and the contact layer sequence 7. The electrically insulating layer 8 has a first recess 9. The first recess 9 completely penetrates the electrically insulating layer 8. The contact layer sequence 7 is in direct and electrically conductive contact with the first sublayer 10 in the first recess 9.

In this exemplary embodiment, the contact layer sequence 7 exclusively comprises a second current spreading layer 13. The second current spreading layer 13 is arranged here in direct contact with a bottom surface of the second semiconductor layer sequence 3. Furthermore, the second current spreading layer 13 is formed with ITO, for example.

A cross-sectional area in vertical direction of the second current spreading layer 13 has a step shape in the direction of the first contact structure 5. The step shape here comprises three steps 24. In the region of the step 24 closest to the first contact structure 5, the cross-sectional area in the vertical direction of the second current spreading layer 13 has a height of approximately 50 nm. In the region of the middle step 24, the cross-sectional area in vertical direction of the second current spreading layer 13 has a height of approximately 167 nm. Furthermore, the cross-sectional area in vertical direction of the second current spreading layer 13 has a height of approximately 300 nm in the region of the step 24 farthest from the first contact structure 5. That is, a cross-sectional area in vertical direction of the second current spreading layer 13 decreases in direction of the first contact structure 5. In this case, the sheet resistance of the contact layer sequence 7 increases in discrete steps in direction of the first contact structure 5.

In lateral direction spaced apart from the second contact structure 6, a third recess 21 extends through the second semiconductor layer sequence 3 to the first semiconductor layer sequence 2. The third recess 21 extends in vertical direction partly into the first semiconductor layer sequence 2 and exposes the first semiconductor layer sequence 2 partly. A first contact structure 5 is arranged in this third recess 21, which is configured to impress charge carriers into the first semiconductor layer sequence 2.

An electrically insulating separation layer 22 is arranged between the first contact structure 5 and the second contact structure 6, as well as between the first contact structure 5 and the second semiconductor layer sequence 3 and the contact layer sequence 7. In this exemplary embodiment, the separation layer 22 comprises two layers, one of the layers having Al₂O₃ and the other of the layers having SiO₂. Furthermore, a contact enhancement layer 23 is arranged between the first contact structure 5 and the first semiconductor layer sequence 2. In this embodiment, the first contact structure 5 and the second contact structure 6 do not overlap in lateral directions in plan view. Alternatively, it is possible that the first contact structure 5 and the second contact structure 6 overlap in lateral directions in plan view.

In contrast to the exemplary embodiment of FIG. 1, the contact layer sequence 7 according to the exemplary embodiment of FIG. 2 comprises a first current spreading layer 12. The first current spreading layer 12 is arranged here in direct contact with a bottom surface of the second semiconductor layer sequence 3. Furthermore, the first current spreading layer 12 and the second current spreading layer 13 are formed with ITO, for example. The first current spreading layer 12 comprises a height in vertical direction of approximately 20 nm.

In addition, the contact layer sequence 7 includes a dielectric layer 14 arranged in regions between the first current spreading layer 12 and the second current spreading layer 13. The dielectric layer 14 is in direct contact with the first current spreading layer 12 and the second current spreading layer 13. Furthermore, the dielectric layer 14 has second recesses 15. The second recesses 15 completely penetrate the dielectric layer 14. The first current spreading layer 12 is in direct and electrically conductive contact with the second current spreading layer 13 in the second recesses 15. The dielectric layer 14 with the second recesses 15 is completely arranged between the first current spreading layer 12 and the second current spreading layer 13.

In contrast to FIG. 1, the first semiconductor layer sequence 2 in the exemplary embodiment of FIG. 3 has a step shape. The step shape here comprises two steps 24. In the region of step 24, which is arranged above the first contact structure 5, the first semiconductor layer sequence 2 has a height of approximately 1.33 μm. In the region of step 24, which is not arranged above the first contact structure 5, the first semiconductor layer sequence 2 has a height of approximately 0.67 μm. That is, a height of the first semiconductor layer sequence 2 increases towards the first contact structure 5.

By such a structured first semiconductor layer sequence 2, the number of steps 24 in the second current spreading layer 13 can be reduced. In contrast to FIG. 1, the second current spreading layer 13 comprises only two steps 24. The step 24 of the second current spreading layer 13 closest to the first contact structure 5 has a height in the vertical direction of 133 nm. The step 24 of the second current spreading layer 13 furthest away from the first contact structure 5 has a height in the vertical direction of 267 nm.

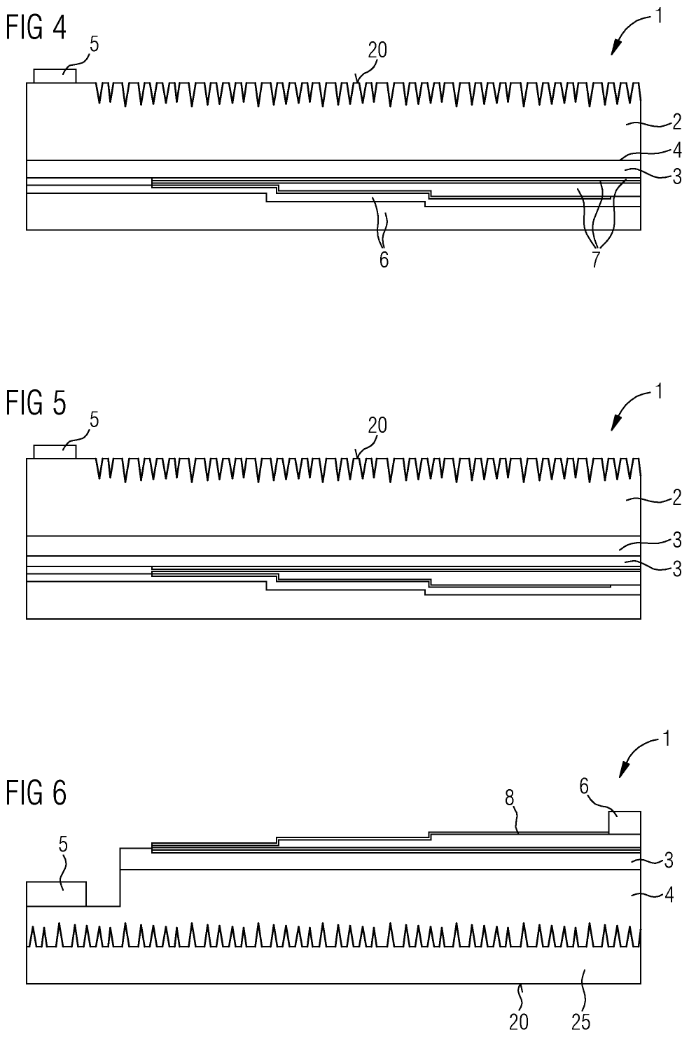

The radiation emitting semiconductor chip 1 of the exemplary embodiment of FIG. 4 does not have a third recess 21, in contrast to the semiconductor chip 1 of FIG. 2. The first contact structure 5 is arranged in direct contact on the first semiconductor layer sequence 2, in particular the radiation exit surface 20. In this exemplary embodiment, the first semiconductor layer sequence 2 is n-doped GaN and the second semiconductor layer sequence 3 is p-doped GaN.

Furthermore, the second contact structure 6 completely covers the second semiconductor layer sequence 3. Thus, the first contact structure 5 and the second contact structure 6 overlap in lateral directions in top view.

In contrast to FIG. 4, the first semiconductor layer sequence 2 according to the exemplary embodiment of FIG. 5 is n-doped InAlP with a height in vertical direction of 3 μm. In this exemplary embodiment, the second semiconductor layer sequence 3 comprises two subregions. The subregion adjacent to the first semiconductor layer sequence 2 comprises, for example, p-doped InAlP. The subregion adjacent to the contact layer sequence 7 comprises, for example, p-doped GaP.

The radiation emitting semiconductor chip 1 of the exemplary embodiment of FIG. 6 comprises, in contrast to the semiconductor chip 1 of FIG. 2, a substrate 25 which is, for example, a growth substrate for the first semiconductor layer sequence 2. The substrate 25 is, for example, a sapphire substrate and has a height in vertical direction of greater than 100 μm.

Furthermore, the first contact structure 5 is arranged in the third recess 21 in direct contact on the first semiconductor layer sequence 2. Furthermore, the first contact structure 6 does not comprise a reflective layer, such as the semiconductor chip in FIG. 2. Moreover, the second contact structure 6 extends along a main extension direction in lateral directions.

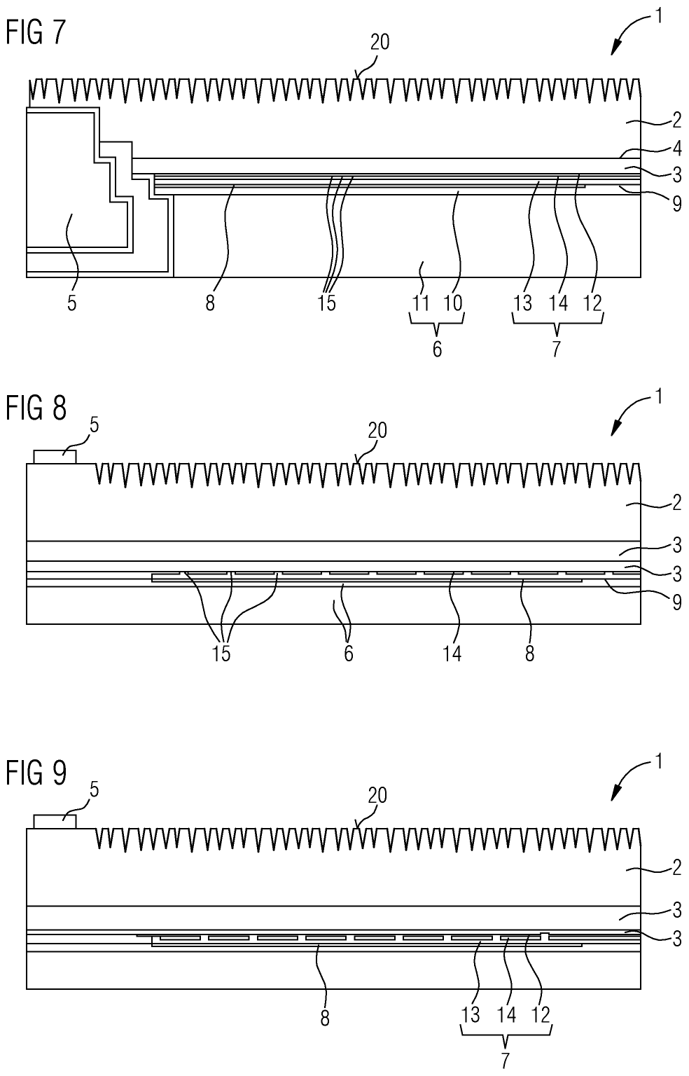

The second current spreading layer 13 of the radiation emitting semiconductor chip 1 according to the exemplary embodiment of FIG. 7 has a constant cross-sectional area in vertical direction, unlike the exemplary embodiment of FIG. 2.

A height of the first current spreading layer 12 in this exemplary embodiment is smaller than a height of the second current spreading layer 13. The height of the first current spreading layer 12 in this exemplary embodiment is approximately 20 nm. The height of the second current spreading layer 13 is approximately 200 nm in this exemplary embodiment.

A cross-sectional area in lateral directions of the second current spreading layer 13 decreases in size towards the first contact structure 5, which is described in more detail in connection with FIGS. 11 and 12.

In contrast to FIG. 7, the first semiconductor layer sequence 2 according to the exemplary embodiment of FIG. 8 is n-doped InAlP with a height in vertical direction of 3 μm. In this exemplary embodiment, the second semiconductor layer sequence 3 comprises two subregions. The subregion adjacent to the first semiconductor layer sequence 2 comprises, for example, p-doped InAlP. The subregion adjacent to the contact layer sequence 7 comprises, for example, p-doped GaP.

Further, the radiation emitting semiconductor chip 1 is free of the first current spreading layer 12. In this case, the second current spreading layer 13 is in direct contact with the second semiconductor layer sequence 3 within the second recesses 15 in the dielectric layer 14.

The contact layer sequence 7 of the radiation emitting semiconductor chip 1 according to the exemplary embodiment of FIG. 9 comprises the first current spreading layer 12 in contrast to the semiconductor chip 1 of FIG. 8.

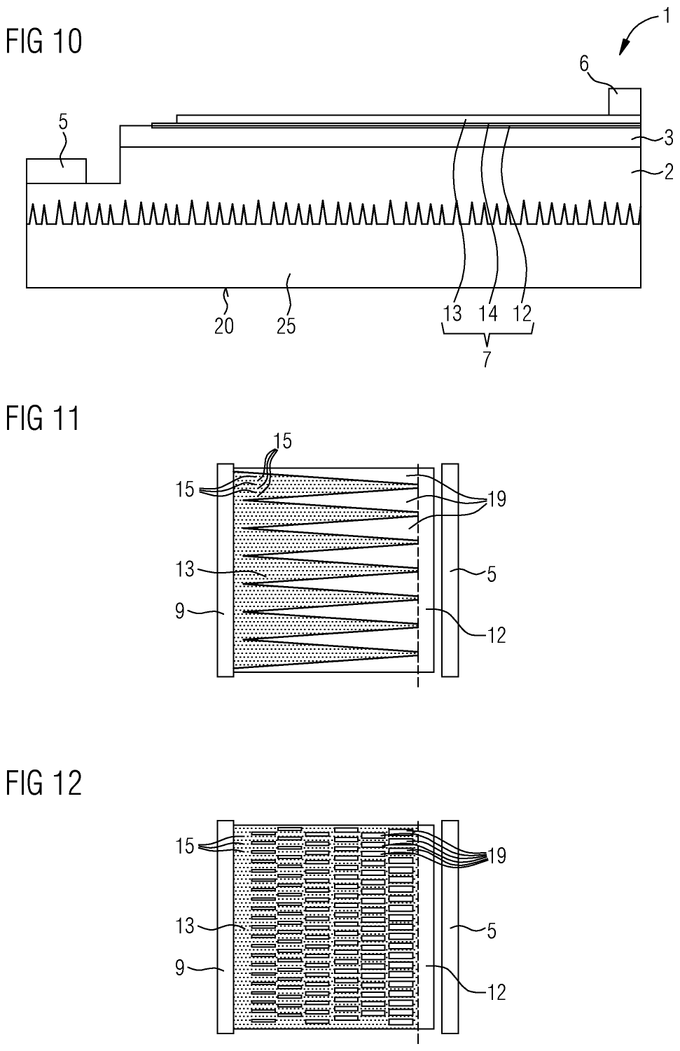

The second current spreading layer 13 of the radiation emitting semiconductor chip 1 according to the exemplary embodiment of FIG. 10 has a constant cross-sectional area in vertical direction in contrast to the exemplary embodiment of FIG. 6, as explained for example in more detail in connection with FIG. 7.

The first current spreading layer 12 extends between the first recess 9 and the first contact structure 5 according to the exemplary embodiment of FIG. 11. In plan view, the first current spreading layer 12 overlaps with the first recess 9 in lateral directions. The dielectric layer 14 is arranged on the first current spreading layer 12, which has second recesses 15. The second current spreading layer 13 is arranged on the dielectric layer 14, which is in direct contact with the first current spreading layer 12 in the second recesses 15.

Furthermore, the second current spreading layer 13 and the dielectric layer 14 are structured so that a cross-sectional area in lateral directions of the second current spreading layer 13 is reduced in direction of the first contact structure 5. For this purpose, openings 19 are formed in the second current spreading layer 13 and the dielectric layer 14.

For example, the openings 19 are shaped such that the cross-sectional area in lateral directions of the second current spreading layer 13 tapers towards the first contact structure 5. In this embodiment, the second current spreading layer 13 structured by the openings 19 has, in plan view, a shape of a plurality of pyramids whose tops are directed towards the first contact structure 5. A base of each pyramid has, for example, a length in lateral directions of at least 10 μm and at most 30 μm. The first recess 9 and the first contact structure 5 have, for example, a minimum distance in lateral directions of at least 10 μm and at most 30 μm.

Furthermore, a region in plan view in lateral directions starting from the first contact structure 5 to the first recess 9 is free of the second current spreading layer 13. This region has a width in lateral directions of at least 10 μm and at most 30 μm.

The second recesses 15 are in addition arranged at grid points of a grid. The grid is in particular a regular hexagonal grid.

In contrast to the exemplary embodiment of FIG. 11, the openings 19 according to FIG. 12 are arranged at further grid points of a further grid. The grid is in particular a stretched hexagonal grid. Furthermore, a cross-sectional area in lateral directions of the openings 19 increases in direction of the first contact structure 5.

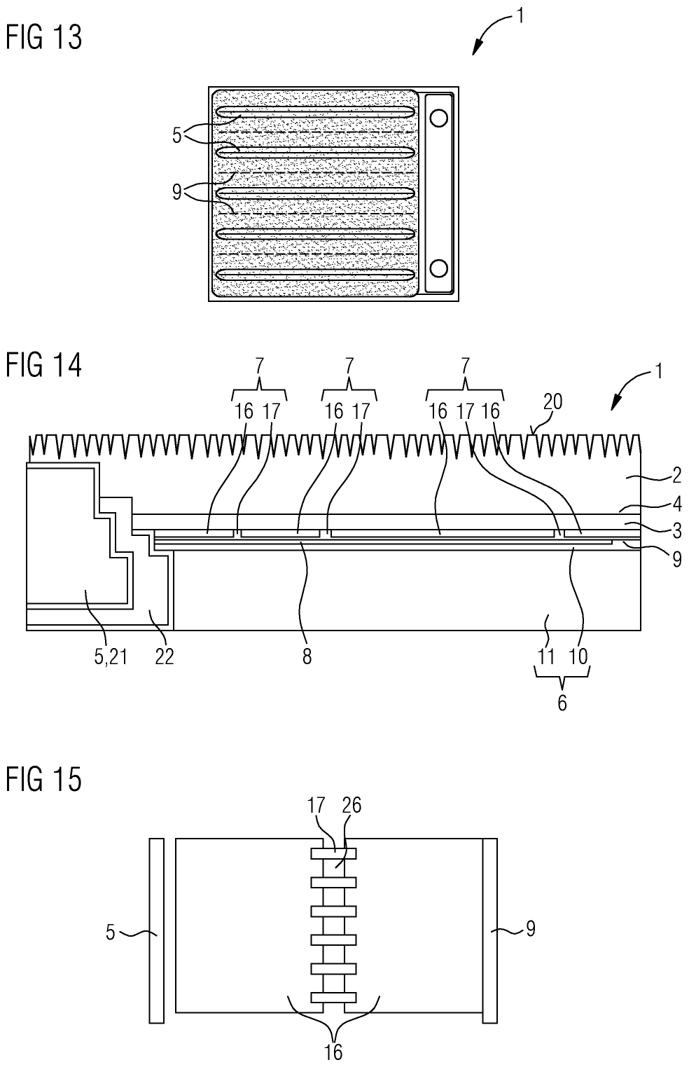

In the radiation emitting semiconductor chip 1 according to the exemplary embodiment of FIG. 13, the first contact structure 5 and the first recess 9 extend parallel to one another. The first contact structure 5 and the first recess 9 each have a length. In particular, the lengths are formed to be equal in size.

According to the exemplary embodiment of FIG. 14, the contact layer sequence 7 of the radiation emitting semiconductor chip 1 has, in contrast to the contact layer sequence 7 of FIG. 1, several metallic subsegments 16. Furthermore, the contact layer sequence 7 comprises at least one connecting layer 17 between directly adjacent metallic subsegments 16. The metallic subsegments 16 are in direct contact with the second semiconductor layer sequence 3. In each case, an area in lateral directions of the metallic subsegments 16 that is in direct contact with the second semiconductor layer sequence 3 decreases in size from the first recess 9 towards the first contact structure 5.

The metallic subsegments 16 are formed with silver, for example. In addition, the connecting layers 17 are formed with ITO, for example.

In the exemplary embodiment shown in FIG. 15, two metallic subsegments 16 of the same size are electrically conductively connected to one another by six connecting layers 17. A trench 26 is arranged between the metallic subsegments 16. The trench 26 has a width in lateral directions of approximately 2 μm. The first recess 9 and the first contact structure 5 are approximately 100 μm apart.

Furthermore, the connecting layers 17 each have a height in lateral directions of approximately 50 nm. In this case, the connecting layers 17 have an area portion of approximately 20% of an area of the trench 26 in plan view in lateral directions.

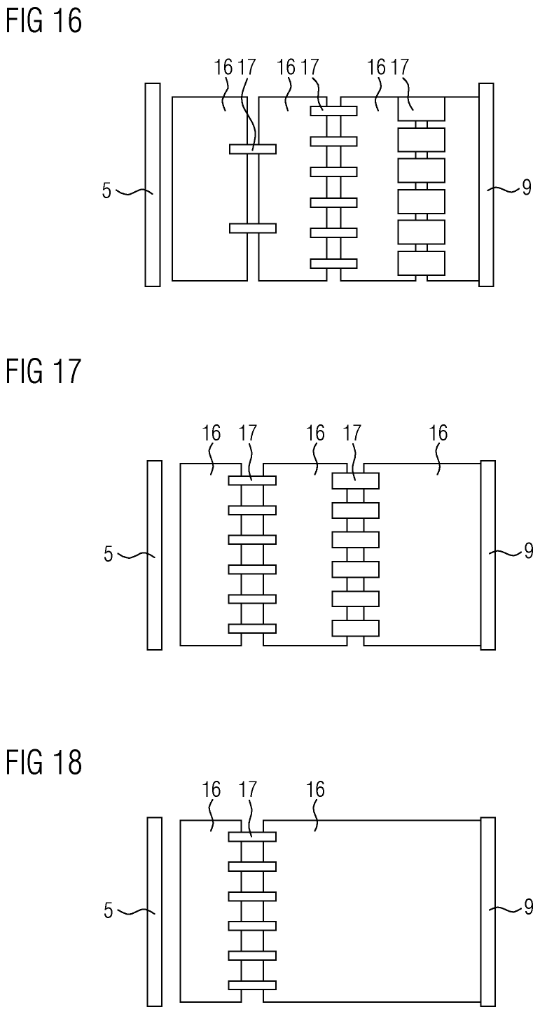

The radiation emitting semiconductor chip 1 according to the exemplary embodiment of FIG. 16 has four metallic subsegments 16, each of which has an area being equal in size in lateral directions. Directly adjacent subsegments 16 have a distance in lateral directions of approximately 2 μm. The first recess 9 and the first contact structure 5 have a distance of approximately 100 μm.

The connecting layers 17 arranged closest to the first contact structure 5 have, for example, an area in lateral directions that is approximately six times smaller than the connecting layers 17 arranged closest to the first recess 9. For example, the connecting layers 17 arranged in the center have an area in lateral directions that is approximately two times smaller than the connecting layers 17 arranged closest to the first recess 9. Thus, a sheet resistance of the contact layer sequence 7 effectively increases from the first recess 9 towards the first contact structure 5.

In contrast to FIG. 16, the radiation emitting semiconductor chip 1 according to the exemplary embodiments of FIGS. 17 and 18 has metallic subsegments 16 of different sizes. An area in lateral directions of the metallic subsegments 16 decreases in direction of the first contact structure 5.

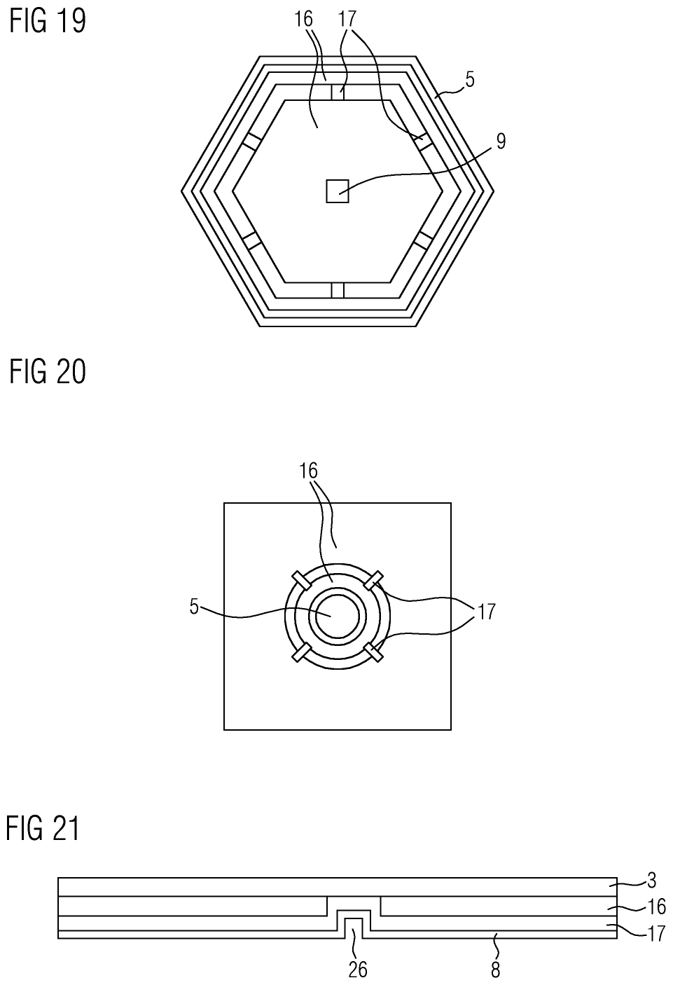

According to the exemplary embodiment of FIG. 19, the first contact structure 5 extends in plan view in lateral directions along a closed shape. The closed shape is a hexagon.

The outer metallic subsegment 16 also extends in plan view in lateral directions along a closed shape corresponding to a hexagon. In this embodiment, the inner metallic subsegment 16 extends in plan view in lateral directions along a simple connected surface having a shape corresponding to a hexagon.

In this embodiment, the second contact structure 5 and/or the first recess 9 extend/extends in plan view in lateral directions along a simple connected surface having a shape of a quadrilateral.

In addition, all metallic subsegments 16 are completely enclosed by the first contact structure 5 in lateral directions.

In contrast to the first contact structure 5 of FIG. 19, the first contact structure 5 according to the exemplary embodiment of FIG. 20 is completely enclosed by each metallic subsegment 16 in lateral directions. Here, in plan view, the first contact structure 5 extends in lateral directions along a simple connected surface which has a shape of a circle.

In the embodiments of FIGS. 21, 22, 23, 24, and 25, a sectional view of a section in a region between directly adjacent metallic subsegments 16 is shown in each case.

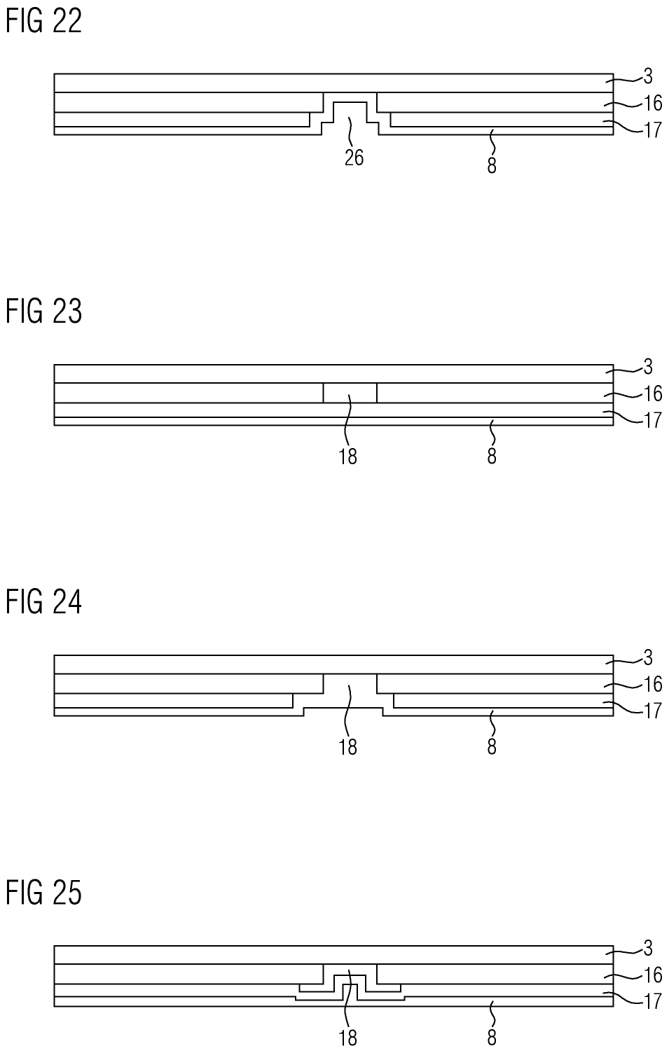

In the embodiments of FIGS. 21, 23 and 26, a sectional view in vertical direction from the first contact structure 5 to the first recess 9 through a connecting layer 17 between directly adjacent metallic subsegments 16 is shown in each case. FIGS. 22 and 24 each show a sectional view in vertical direction from the first contact structure 5 to the first recess 9 between directly adjacent metallic subsegments 16, where the connecting layer 17 is not arranged.

Directly adjacent metallic subsegments 16 are electrically conductively connected by the connecting layer 17, as shown in FIG. 21. The connecting layer 17 between directly adjacent metallic subsegments 16 is arranged between the second semiconductor layer 3 and the electrically insulating layer 8. Furthermore, the connecting layer 17 between directly adjacent metallic subsegments 16 is in direct contact with the second semiconductor layer 3.

A trench 26 between directly adjacent metallic subsegments 16 is completely covered by the electrically insulating layer 8 in the region where the connecting layer 17 is not arranged, as shown in FIG. 22.

According to FIG. 23, a further dielectric layer 18 is arranged in lateral directions between the subsegments 16. In this case, the further dielectric layer 18 is arranged completely in regions between the metallic subsegments 16. The connecting layer 17 is further arranged between the further dielectric layer 18 and the electrically insulating layer 8.

According to FIG. 24, the further dielectric layer 18 is in direct contact with the electrically insulating layer 8, in the region where the connecting layer 17 is not arranged.

In contrast to FIG. 23, the connecting layer 17 according to FIG. 25 extends in regions in lateral directions and in regions in vertical directions. Due to such an extension, the connecting layer 17 is extended in comparison to an connecting layer 17 extending only in lateral directions between the subsegments 16, as shown for example in FIG. 23.

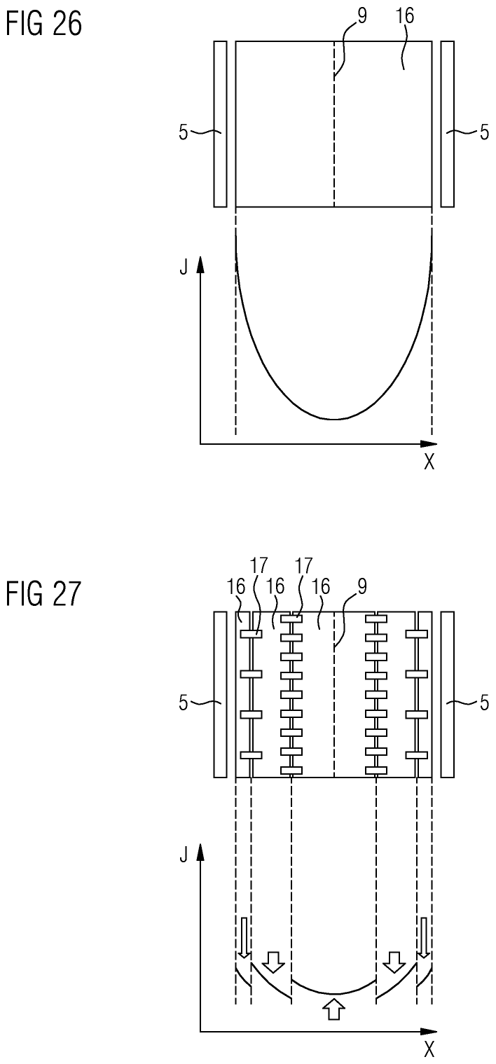

A current density J in the active region 4 is shown in FIG. 26 as an example for a radiation emitting semiconductor chip with only a single metallic subsegment 16. Here x indicates a position in lateral directions from the first contact structure 5 to the first recess 9. The current density J has a parabolic shape. In this case, the current density J can differ by a factor of approximately 2 to 5.

FIG. 26 shows a current density J in the active region 4 as an example of a radiation emitting semiconductor chip 1 described here, in which several metallic subsegments 16 are electrically conductively connected to one another by connecting layers 17. In this case, the current density J differs by a factor smaller than 1.5.

The features and exemplary embodiments described in connection with the Figures can be combined with each other according to further exemplary embodiments, even if not all combinations are explicitly described. Furthermore, the exemplary embodiments described in connection with the Figures can alternatively or additionally have further features according to the description in the general part.

The invention is not limited to these exemplary embodiments by the description based on the exemplary embodiments. Rather, the invention encompasses any new feature as well as any combination of features, which in particular includes any combination of features in the patent claims, even if this feature or combination itself is not explicitly stated in the patent claims or exemplary embodiments.

This patent application claims the priority of the German patent application 10 2020 114 772.4, the disclosure content of which is hereby incorporated by reference.

### LIST OF REFERENCE SIGNS

1 radiation emitting semiconductor chip
2 first semiconductor layer sequence
3 second semiconductor layer sequence
4 active region
5 first contact structure
6 second contact structure
7 contact layer sequence
8 electrically insulating layer
9 first recess
10 first sublayer
11 second sublayer
12 first current spreading layer
13 second current spreading layer
14 dielectric layer
15 second recesses
16 metallic subsegment
17 connecting layer
18 further dielectric layer
19 opening
20 radiation exit surface
21 third recess
22 electrically insulating separation layer
23 contact enhancement layer
24 steps
25 substrate
26 trench

1. A radiation emitting semiconductor chip comprising:
a first semiconductor layer sequence;
a second semiconductor layer sequence arranged on the first semiconductor layer sequence;
a first contact structure configured to inject charge carriers into the first semiconductor layer sequence; and
a contact layer sequence configured to inject charge carriers into the second semiconductor layer sequence;
wherein:
the first contact structure and the contact layer sequence are formed without overlapping in lateral directions in plan view; and
the contact layer sequence has a sheet resistance, which increases in direction of the first contact structure.

2. The emitting semiconductor chip according to claim 1,
wherein:
a second contact structure is arranged on the contact layer sequence;
an electrically insulating layer is arranged in regions between the second contact structure and the contact layer sequence; and
the electrically insulating layer has at least one first recess in which the second contact structure and the contact layer sequence are in electrically conductive contact.

3. The emitting semiconductor chip according to claim 2, wherein
the second contact structure comprises a first sublayer and a second sublayer.

4. The emitting semiconductor chip according to claim 1,
wherein the contact layer sequence comprises a first current spreading layer in direct contact with the second semiconductor layer sequence.

5. The emitting semiconductor chip according to claim 1,
wherein the contact layer sequence comprises a second current spreading layer which is in regions in direct contact with the second contact structure.

6. The emitting semiconductor chip according to claim 4,
wherein a height in vertical direction of the first current spreading layer is smaller than a height in vertical direction of a second current spreading layer.

7. The emitting semiconductor chip according to claim 5,
wherein a cross-sectional area in vertical direction of the second current spreading layer decreases towards the first contact structure.

8. The emitting semiconductor chip according to claim 5,
wherein a cross-sectional area in lateral directions of the second current spreading layer decreases towards the first contact structure.

9. The emitting semiconductor chip according to claim 4,
wherein the contact layer sequence comprises a dielectric layer which is arranged in regions between the first current spreading layer and the second current spreading layer.

10. The emitting semiconductor chip according to claim 9,
wherein:
the dielectric layer has second recesses; and
the first current spreading layer is in direct contact with the second current spreading layer in the second recesses.

11. The emitting semiconductor chip according to claim 1,
wherein:
the contact layer sequence comprises at least two metallic subsegments and at least one connecting layer;
the connecting layer electrically conductively connects the metallic subsegments; and
a resistance of the connecting layer is larger than each resistance of the metallic subsegments.

12. The emitting semiconductor chip according to claim 11,
wherein the first contact structure is completely enclosed by each metallic subsegment in lateral directions.

13. The emitting semiconductor chip according to claim 11,
wherein all metallic subsegments are completely enclosed by the first contact structure in lateral directions.

14. The emitting semiconductor chip according to claim 11,
wherein a further dielectric layer is arranged in lateral directions between the metallic subsegments.

15. The emitting semiconductor chip according to claim 14,
wherein the connecting layer is arranged between the further dielectric layer and the electrically insulating layer.

16. The emitting semiconductor chip according to claim 15,
wherein a length of the connecting layer between the metallic subsegments predetermines a sheet resistance of the contact layer sequence.

17. The emitting semiconductor chip according to claim 2,
wherein the first contact structure and the first recess extend parallel to one another.

18. The emitting semiconductor chip according to claim 1, wherein:
an active region is arranged between the first semiconductor layer sequence and the second semiconductor layer sequence;
the active region is configured to generate electromagnetic radiation; and
the sheet resistance of the contact layer sequence is predetermined such that an average current density in the active region does not deviate by more than 10% from a predetermined average current density.
